(19) United States
(12) Patent Application Publication
(10) Pub. No.: US 2023/0369174 A1
(43) Pub. Date: Nov. 16, 2023

(54) SEMICONDUCTOR STRUCTURE

(71) Applicant: CHANGXIN MEMORY TECHNOLOGIES, INC., Hefei City (CN)

(72) Inventor: Miaomiao CHEN, Hefei (CN)

(21) Appl. No.: 18/166,025

(22) Filed: Feb. 8, 2023

Related U.S. Application Data
(63) Continuation of application No. PCT/CN2022/100223, filed on Jun. 21, 2022.

(30) Foreign Application Priority Data
May 11, 2022 (CN) 202210511132.5

(51) Int. Cl. H01L 23/482; H01L 23/528; H01L 23/00

(52) U.S. Cl. CPC H01L 23/4824; H01L 23/5283; H01L 24/46; H01L 2224/46; H01L 2924/1011

(57) ABSTRACT

Provided is a semiconductor structure, configured to form a pad, including a substrate, a top-layer conductive line, N layers of secondary-top-layer conductive lines and a plurality of dielectric layers, N being an integer greater than or equal to 2. The top-layer conductive line and the N layers of the secondary-top-layer conductive lines are arranged above the substrate. The N layers of the secondary-top-layer conductive lines are arranged on a side of the top-layer conductive line close to the substrate. Each of the plurality of dielectric layers is located between two respective adjacent layers of the secondary-top-layer conductive lines in a vertical direction. For the N layers of the secondary-top-layer conductive lines, an area in which projections of any two layers of the secondary-top-layer conductive lines on a top surface of the substrate overlap with each other is less than a first threshold.

### CROSS-REFERENCE OF RELATED APPLICATIONS

This is a continuation of International Application No. PCT/CN2022/100223, filed on Jun. 21, 2022, which is based on and claims priority of Chinese Patent Application No. 202210511132.5, filed on May 11, 2022. The contents of International Application No. PCT/CN2022/100223 and Chinese Patent Application No. 202210511132.5 are hereby incorporated by reference in their entireties.

### TECHNICAL FIELD

The disclosure relates to the technical field of integrated circuits, and in particular to a semiconductor structure.

### BACKGROUND

In the semiconductor package techniques, as pins of a chip, pads can not only process an input signal from exterior of the chip pin and transfer the input signal to interior of the chip, but also process an output signal from the interior of the chip and transfer the output signal to the exterior of the chip. Therefore, design of the structure of the pads greatly influences performance of the chip.

In the related art, uneven density of bottom of a pad would cause the pad to lack effective support and be worn easily in subsequent processes, and even cause a short circuit in serious cases. Meanwhile, a parasitic capacitance at the structure of the pad is large, which result in an increased signal delay and increased power consumption, thus affecting the performance of the chip.

### SUMMARY

Embodiments of the present disclosure provide a semiconductor structure configured to form a pad. The semiconductor structure includes a substrate, a top-layer conductive line, N layers of secondary-top-layer conductive lines and multiple dielectric layers. N is an integer greater than or equal to 2.

The top-layer conductive line and the N layers of the secondary-top-layer conductive lines are arranged above the substrate. The N layers of the secondary-top-layer conductive lines are arranged on a side of the top-layer conductive line close to the substrate, and each of the multiple dielectric layers is located between two respective adjacent layers of the secondary-top-layer conductive lines in a vertical direction.

For the N layers of the secondary-top-layer conductive lines, an area in which projections of any two layers of the secondary-top-layer conductive lines on a top surface of the substrate overlap with each other is less than a first threshold.

### BRIEF DESCRIPTION OF THE DRAWINGS

FIG. 1 is a first diagram of a semiconductor structure according to an embodiment of the present disclosure.

FIG. 2 is a second diagram of a semiconductor structure according to an embodiment of the present disclosure.

FIG. 3 is a third diagram of a semiconductor structure according to an embodiment of the present disclosure.

FIG. 4 is a fourth diagram of a semiconductor structure according to an embodiment of the present disclosure.

FIG. 5 is a fifth diagram of a semiconductor structure according to an embodiment of the present disclosure.

FIG. 6 is a sixth diagram of a semiconductor structure according to an embodiment of the present disclosure.

FIG. 7 is a seventh diagram of a semiconductor structure according to an embodiment of the present disclosure.

FIG. 8 is an eighth diagram of a semiconductor structure according to an embodiment of the present disclosure.

FIG. 9 is a ninth diagram of a semiconductor structure according to an embodiment of the present disclosure.

FIG. 10 is a tenth diagram of a semiconductor structure according to an embodiment of the present disclosure.

FIG. 11 is an eleventh diagram of a semiconductor structure according to an embodiment of the present disclosure.

FIG. 12 is a twelfth diagram of a semiconductor structure according to an embodiment of the present disclosure.

FIG. 13 is a thirteenth diagram of a semiconductor structure according to an embodiment of the present disclosure.

FIG. 14 is a fourteenth diagram of a semiconductor structure according to an embodiment of the present disclosure.

FIG. 15 is a fifteenth diagram of a semiconductor structure according to an embodiment of the present disclosure.

FIG. 16 is a sixteenth diagram of a semiconductor structure according to an embodiment of the present disclosure.

FIG. 17 is a seventeenth diagram of a semiconductor structure according to an embodiment of the present disclosure.

### DETAILED DESCRIPTION

In order to make the purposes, technical solutions and advantages of the present disclosure clearer, the technical solutions of the present disclosure would be further described in detail below in combination with the drawings and embodiments. The described embodiments should not be considered as limitations on the present disclosure, and all other embodiments obtained by those skilled in the art without creative efforts should be considered to be within the scope of protection of the present disclosure.

In the following description, the expression “some embodiments” refers to a subset of all possible embodiments. However, it should be understood that the expression “some embodiments” may be the same subset or different subsets of all possible embodiments and may be combined with each other without conflict.

If the expressions “first” and “second” or the like appear in the document of the present disclosure, the following explanation should be involved. In the following description, The expressions “first”, “second” and “third” involved are only used for distinguishing similar objects and are not intended to imply a specific order of objects. It should be understood that specific order or sequence of the expressions “first”, “second” and “third” may be interchanged where permissible so as to enable that the embodiments of the present disclosure described herein can be implemented in an order other than that illustrated or described herein.

Unless otherwise defined, all technical and scientific terms used herein have the same meanings as are commonly understood by those skilled in the art of the present disclosure. The terms used herein are for the purpose of describing embodiments of the present disclosure only and are not intended to limit the present disclosure.

Parasitic capacitance is a capacitance characteristic exhibited by two conductors in transmitting high-frequency signals, which can bring interference to the transmitted signals. A value of the parasitic capacitance is directly proportional to an area in which the two conductors face with each other, and is inversely proportional to a distance between the two conductors.

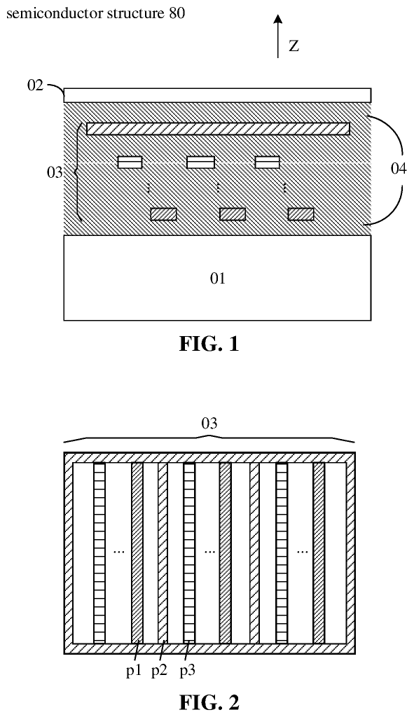

FIG. 1 illustrates a diagram of an optional structure of a semiconductor structure according to an embodiment of the present disclosure. As illustrated in FIG. 1, a semiconductor structure 80 is configured to form a pad. The pad includes a substrate 01, a top-layer conductive line 02, N layers of secondary-top-layer conductive lines 03 and multiple dielectric layers 04. N is greater than or equal to 2. The top-layer conductive line 02 and the N layers of the secondary-top-layer conductive lines 03 are arranged above the substrate 01. The N layers of the secondary-top-layer conductive lines 03 are arranged on a side of the top-layer conductive line 02 close to the substrate 01, and each of the multiple dielectric layers 04 is located between two respective adjacent layers of the secondary-top-layer conductive lines 03 in a vertical direction Z, or between the N layers of the secondary-top-layer conductive lines 03 and the top-layer conductive line 02.

In the embodiment of the present disclosure, referring to FIG. 1, the secondary-top-layer conductive lines 03 are stacked into N layers in the vertical direction Z, which are represented by different hatch patterns. For the N layers of the secondary-top-layer conductive lines 03, an area in which projections of any two layers of the secondary-top-layer conductive lines 03 on a top surface of the substrate 01 overlap with each other is less than a first threshold.

In some embodiments of the present disclosure, in combination with FIGS. 1 and 2, which illustrate an optional structure of the secondary-top-layer conductive lines 03, a projection of the N layers of the secondary-top-layer conductive lines 03 on the top surface of substrate 01 forms patterns such as p1, p2 and p3. Each of the patterns p1, p2 and p3 corresponds to a respective layer of the secondary-top-layer conductive lines 03. In FIG. 2, the patterns p1, p2 and p3 do not overlap each other. That is, projections of any two of the N layers of the secondary-top-layer conductive lines 03 on the top surface of the substrate 01 do not overlap with each other. In other words, the area of the overlapping parts is 0, which meets a limit of being less than the first threshold.

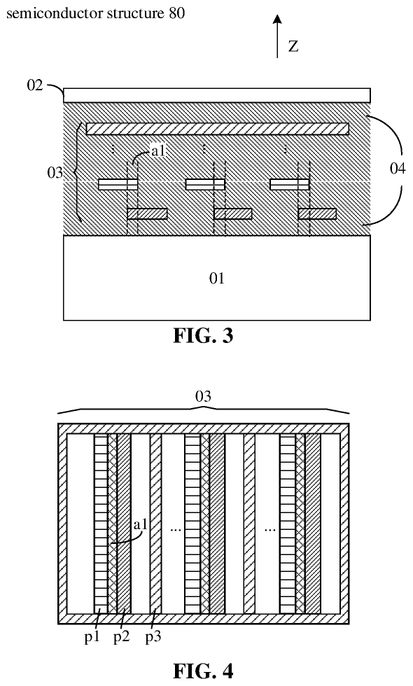

In some embodiments of the present disclosure, in combination with FIGS. 3 and 4, which illustrate another optional structure of the secondary-top-layer conductive lines 03, the projection of the N layers of the secondary-top-layer conductive lines 03 on the top surface of substrate 01 forms patterns such as p1, p2 and p3. Each of the patterns p1, p2 and p3 corresponds to a respective layer of the secondary-top-layer conductive lines 03. In FIG. 4, there is an overlapping part a1 between the pattern p1 and the pattern p2. That is, projections of two layers of the secondary-top-layer conductive lines 03 on the top surface of the substrate 01 have the overlapping part a1.

It should be noted that the capacitance can be calculated by the following formula:

$$C = \frac{ε S}{4 π k d} \qquad ( 1 )$$

C is the capacitance, E is a dielectric constant, S is an area in which capacitor plates face with each other, k is an electrostatic force constant, and d is a distance between the capacitor plates.

On one hand, it can be seen from the formula (1) for calculating the capacitance that a value of the parasitic capacitance is directly proportional to an area in which the two conductors (which are capacitance plates) generating the parasitic capacitance face each other. Therefore, the area in which projections of any two layers of the secondary-top-layer conductive lines 03 on the top surface of the substrate 01 overlap with each other is controlled to be less than the first threshold (i.e. an area in which the two layers of the secondary-top-layer conductive lines 03 face each other is reduced), which can reduce the parasitic capacitance.

On the other hand, the N layers of the secondary-top-layer conductive lines 03 are arranged on one side of the top-layer conductive line 02 close to the substrate 01, and each of the multiple dielectric layers 04 is located between two respective adjacent layers of the secondary-top-layer conductive lines 03 in a vertical direction Z. That is, the secondary-top-layer conductive lines 03 and the multiple dielectric layers 04 are alternately arranged below the top-layer conductive line 02, thereby improving density uniformity of material under the top-layer conductive line 02 and meeting planarization requirements in subsequent Chemical Mechanical Polishing (CMP) and other processes.

In some embodiments of the present disclosure, a material of the dielectric layers 04 illustrated in FIGS. 1 and 3 is an insulating material, and a material of the top-layer conductive line 02 and a material of the N layers of the secondary-top-layer conductive lines 03 are metal. On one hand, the dielectric layers 04 isolates the top-layer conductive line 02 and the N layers of the secondary-top-layer conductive lines 03, and isolates adjacent secondary-top-layer conductive lines 03, thereby avoiding short circuit. On the other hand, the dielectric layers 04 can support the top-layer conductive line 02 and the secondary-top-layer conductive lines 03, thereby improving stability of the semiconductor structure 80.

It should be noted that, as illustrated in FIGS. 1 and 3, gaps filled with air (gaps between gray filling areas) may exist between the dielectric layers 04. That is, air gaps are formed. Since a dielectric constant of air is smaller than a dielectric constant of the insulating material of the dielectric layers 04, it can be seen in combination with the formula (1) that the air gaps can reduce the parasitic capacitance between the secondary-top-layer conductive lines 03.

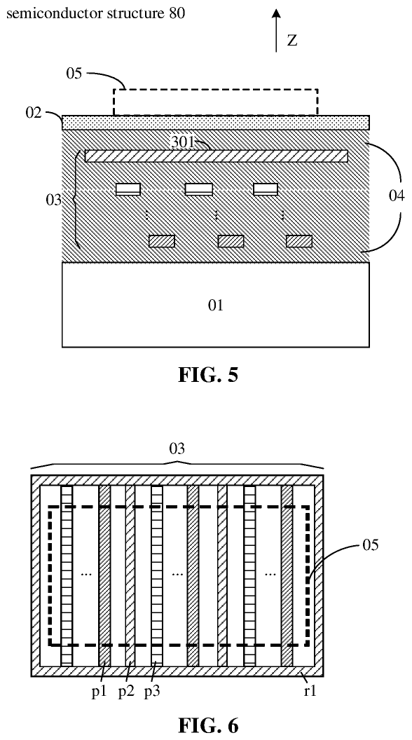

In some embodiments of the present disclosure, as illustrated in FIG. 5, the semiconductor structure 80 further includes a first region 05 configured to form a Redistribution Layer (RDL). The first region 05 is arranged on a side of the top-layer conductive line 02 away from the substrate 01.

In the embodiment of the present disclosure, the first region 05, which is configured to form the RDL, is arranged on the side of the top-layer conductive line 02 away from the substrate 01. It should be noted that the RDL can lead the in-chip circuit pins to appropriate positions to form bums or pads, and an in-chip circuit is conductive to an out-of-chip circuit through the bumps or pads. That is, the RDL can rearrange the in-chip circuit pins.

In the embodiment of the present disclosure, before forming the RDL, a filling dielectric layer can be formed on the top-layer conductive line 02. A first opening is formed in the filling dielectric layer to reserve a region for the RDL to be formed, which is the first region 05.

In the embodiment of the present disclosure, the projection of the N layers of the secondary-top-layer conductive lines 03 on the top surface of the substrate 01 at least partially overlaps with a projection of the first region 05 on the top surface of the substrate 01. FIGS. 5 and 6 illustrate an optional structure of the secondary-top-layer conductive lines 03 and the first region 05. In combination with FIGS. 5 and 6, the projection of the N layers of the secondary-top-layer conductive lines 03 on the top surface of the substrate 01 forms patterns such as p1, p2 and p3. Each of the patterns p1, p2 and p3 corresponds to a respective layer of the secondary-top-layer conductive lines 03. As illustrated in FIG. 6, each of the patterns p1, p2 and p3 overlaps with the projection of the first region 05 on the top surface of the substrate 01 (i.e. parts surrounded by a dashed line frame). That is, at least part of the N layers of the secondary-top-layer conductive lines 03 is arranged directly below the first region 05.

It can be understood that the N layers of the secondary-top-layer conductive lines 03 are arranged lower than the first region 05 in the vertical direction. Therefore, the projection of the N layers of the secondary-top-layer conductive lines 03 on the top surface of substrate 01 and the projection of the first region 05 on the top surface of substrate 01 at least partially overlap. That is, at least part of the N layers of the secondary-top-layer conductive lines 03 is arranged directly below the first region 05, so that the N layers of the secondary-top-layer conductive lines 03 can form an effective support for the first region 05, thereby improving the stability of the semiconductor structure 80. At the same time, the N layers of the secondary-top-layer conductive lines 03 are arranged directly below the first region 05, so as to improve a density uniformity of an area directly below the first region 05 and improve the flatness of the top-layer conductive line 02, thereby avoiding wear and even short circuit caused by uneven density in the subsequent CMP and other technological processes.

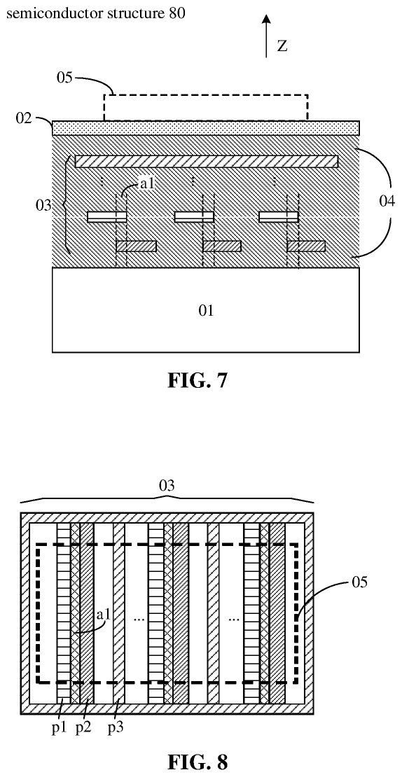

In some embodiments of the present disclosure, FIGS. 7 and 8 illustrate another optional structure of the secondary-top-layer conductive lines 03 and the first region 05. In combination with FIGS. 7 and 8, the projection of the N layers of the secondary-top-layer conductive lines 03 on the top surface of the substrate 01 forms patterns such as p1, p2 and p3. Each of the patterns p1, p2 and p3 corresponds to a respective layer of the secondary-top-layer conductive lines 03. As illustrated in FIG. 8, there is an overlapping part a1 of the pattern p1 and the pattern p2. That is, projections of two layers of the secondary-top-layer conductive lines 03 on the top surface of the substrate 01 have the overlapping part a1. At the same time, each of the patterns p1, p2 and p3 overlaps with the projection of the first region 05 on the top surface of the substrate 01 (i.e. parts surrounded by a dashed line frame). That is, at least part of the N layers of the secondary-top-layer conductive lines 03 is arranged directly below the first region 05. Since projections of two layers of the secondary-top-layer conductive lines 03 on the top surface of the substrate 01 have the overlapping part a1, the N layers of the secondary-top-layer conductive lines 03 are more densely distributed in the area directly below the first region 05, so that the first region 05 can be more effectively supported, and the density uniformity in the area directly below the first region 05 can be more effectively improved. The flatness of the top-layer conductive lines 02 can be better.

In some embodiments of the present disclosure, referring to FIGS. 5 and 6, the N layers of the secondary-top-layer conductive lines 03 include at least one first secondary-top-layer conductive line 301. The first secondary-top-layer conductive line 301 is closest to the top-layer conductive line 02 among the N layers of the secondary-top-layer conductive lines 03. A projection of the first secondary-top-layer conductive line 301 on the top surface of the substrate 01 includes patterns p2 and r1, which cover the projection of the first region 05 on the top surface of the substrate 01.

It can be understood that the projection of the first secondary-top-layer conductive line 301 on the top surface of the substrate 01 covers the projection of the first region 05 on the top surface of the substrate 01, which means that a distribution area of the first secondary-top-layer conductive line 301 covers the area directly below the first region 05, so that the first region 05 can be more effectively supported, and the density uniformity in the area directly below the first region 05 can be more effectively improved. The flatness of the top-layer conductive lines 02 can be better.

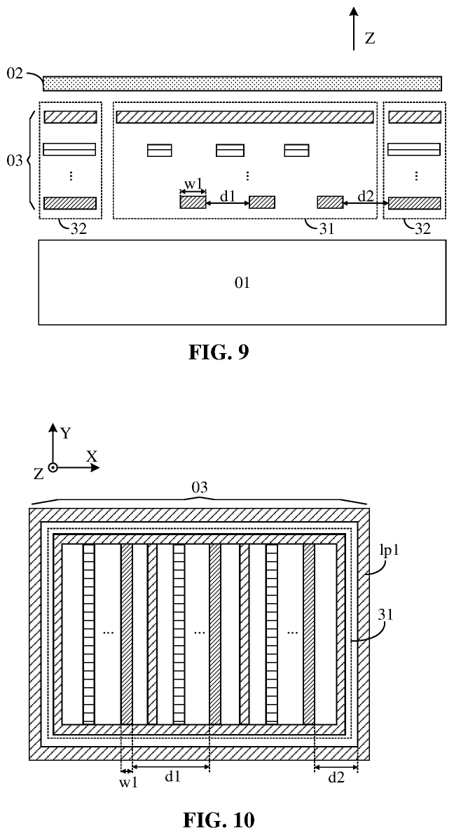

In some embodiments of the present disclosure, in combination with FIGS. 9 and 10, the N layers of the secondary-top-layer conductive lines 03 include central area wires 31. A projection of the central area wires 31 on the top surface of the substrate 01 includes multiple patterns extending in a first direction Y. The multiple patterns are spaced in a second direction X. The second direction X is perpendicular to the first direction Y. For the multiple patterns, a spacing d1 in the second direction X between two adjacent patterns corresponding to each layer of the secondary-top-layer conductive lines 03 is greater than or equal to a second threshold, and a respective maximum width w1 of each of the multiple patterns in the second direction X is less than or equal to a third threshold. It should be noted that the “two adjacent patterns corresponding to each layer of the secondary-top-layer conductive lines” mentioned here refers to that the wires corresponding to the two adjacent patterns are the secondary-top-layer conductive lines of the same layer, which are two adjacent patterns with the same hatch in FIG. 9 and FIG. 10.

It can be seen from the formula (1) for calculating the capacitance that the value of the parasitic capacitance is directly proportional to the area in which the two conductors (which are capacitance plates) generating the parasitic capacitance face each other, and is inversely proportional to a distance between two conductors. Therefore, on one hand, the spacing d1 in the second direction X between two adjacent patterns corresponding to each layer of the secondary-top-layer conductive lines 03 is controlled to be greater than or equal to the second threshold, so that a spacing between respective adjacent parts of each layer of the central area wires 31 is increased, thereby reducing the parasitic capacitance. On the other hand, the respective maximum width w1 of each of the multiple patterns in the second direction X is controlled to be less than or equal to a third threshold, so that an area in which any two layer of central area wires 31 face each other is reduced, thereby reducing the parasitic capacitance.

In some embodiments of the present disclosure, in combination with FIGS. 9 and 10, the N layers of the secondary-top-layer conductive lines 03 further include peripheral area wires 32. A projection of the peripheral area wires 32 on the top surface of the substrate 01 includes a first annular pattern 1p1, and the first annular pattern 1p1 surrounds the projection of the central area wires 31 on the top surface of the substrate 01. A minimum spacing d2 between the projection of the peripheral area wires 32 on the top surface of the substrate 01 and the projection of the central area wires 31 on the top surface of the substrate 01 is greater than or equal to a fourth threshold.

It can be seen from the formula (1) for calculating the capacitance that the value of the parasitic capacitance is inversely proportional to the distance between two conductors (which are capacitance plates) generating the parasitic capacitance. Therefore, the spacing d2 between the projection of the peripheral area wires 32 on the top surface of the substrate 01 and the projection of the central area wires 31 on the top surface of the substrate 01 is controlled to be greater than or equal to a fourth threshold, so that a respective spacing between the central area wires 31 and the peripheral area wires 32 of each layer of the secondary-top-layer conductive lines 03 is increased, thereby reducing the parasitic capacitance.

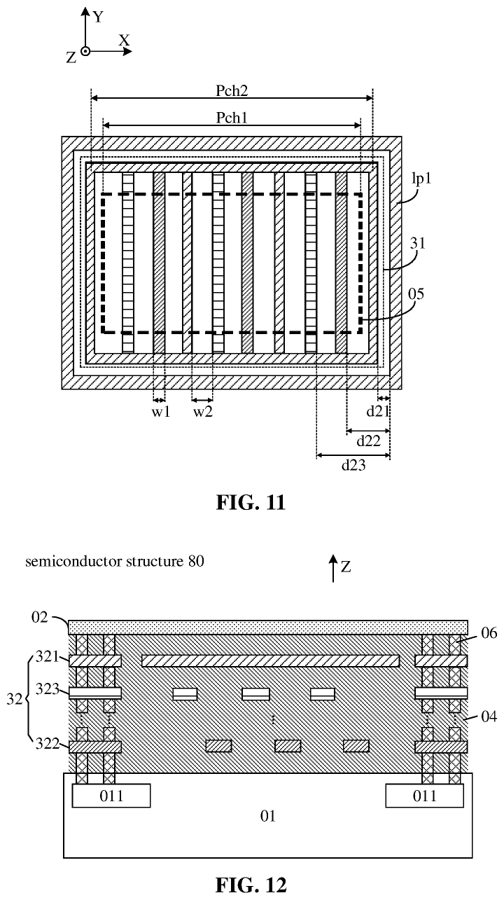

In the embodiment of the present disclosure, sizes of the central area wires 31 and the peripheral area wires 32 can be determined by the following operations. In combination with FIGS. 9 and 11, FIG. 11 illustrates the projections of the first region 05, central area wires 31 and the peripheral area wires 32 on the substrate 01. A size of the first region 05 may be determined according to a size of the pad to be formed. For example, if a width of the pad to be formed is 45 μm, a width Pch1 of the first region 05 may be determined to be 45 μm.

The size of the first region 05 is extended outward by a certain size amount to obtain a size Pch2 of the central area wires 31 (i.e. a width of the projection of the central area wires 31 on the substrate 01). For example, the width Pch1 of the first region 05 is extended to 48 μm, which is determined to be the size Pch2 of the central area wires 31.

The size Pch2 of the central area wires 31 is divided according to a preset number of layers of the secondary-top-layer conductive lines 03 and a number of groups of patterns of the projection of the central area wires 31, thereby obtaining the width w1 of each pattern and a spacing w2 of adjacent patterns in the projection of the central area wires 31. For example, if a preset number of layers of the secondary-top-layer conductive lines 03 is 3 and the number of groups of patterns of the projection of the central area wires 31 is 8, the size Pch2 of the central area wires 31 may be divided by the number of groups of patterns of the projection of the central area wires 31 (48 μm is divided by 8), and a size that can be divided by each group of patterns of the projection of the central area wires 31 is 6 μm. The 6 μm is divided into three layers of secondary-top-layer conductive lines 03 (i.e. 6 μm is divided by 3), and a sum of the width w1 of each pattern and the spacing w2 of adjacent patterns is 2 μm. The width w1 of each pattern is determined to be 1 μm and the spacing w2 of adjacent patterns is determined to be 1 μm.

Accordingly, after determining the width w1 of each pattern and the spacing w2 of adjacent patterns, distances d21, d22 and d23 between different patterns of the central area wires 31 and the peripheral area wires 32 can be further determined. For example, if the width w1 of each pattern is 1 μm and the spacing w2 of adjacent patterns is 1 μm, it can be determined that a nearest distance d21 between the patterns of the central area wires 31 and the peripheral area wires 32 is also 1 μm. Further, on the basis of d21, the values of w1 and w2 are increased, (i.e. increased by 2 μm, so that the distance d22 between a next pattern of the central area wires 31 and the peripheral area wires 32 is 3 μm. By analogy, the values of w1 and w2 are increased on the basis of d22 so that the distance d23 between the yet next pattern of the central area wires 31 and the peripheral area wires 32 is 5 μm.

In some embodiments of the present disclosure, as illustrated in FIG. 12, in a case that N is greater than 2 (i.e. the number of layers of the secondary-top-layer conductive lines is greater than 2), the peripheral area wires 32 include first peripheral area wires 321, second peripheral area wires 322, and at least one layer of third peripheral area wires 323. The first peripheral area wires 321, the at least one layer of the third peripheral area wires 323 and the second peripheral area wires 322 are continuously arranged in the vertical direction Z, and are sequentially arranged in a direction away from the top-layer conductive line 02.

As illustrated in FIG. 12, a first end of the first peripheral area wires 321 is connected to the top-layer conductive line 02, a second end of the first peripheral area wires 321 is connected to a first end of the at least one layer of the third peripheral area wires 323, a first end of the second peripheral area wires 322 is connected to a second end of the at least one layer of the third peripheral area wires 323, and a second end of the second peripheral area wires 322 is connected to a semiconductor test device 011 formed in the substrate 01.

It can be understood that the first end of the first peripheral area wires 321 is connected to the top-layer conductive line 02, the second end of the second peripheral area wires 322 is connected to the semiconductor test device 011, and the remaining peripheral area wires 32 are sequentially connected, so that the top-layer conductive line 02 and the semiconductor test device 011 can be electrically connected. The semiconductor structure provided by the embodiments of the present disclosure may be configured to form the pad. The pad is configured to electrically connect the chip to a package substrate, so that the peripheral area wires 32 can electrically connect the top-layer conductive line 02 and the semiconductor test device 011 in the chip, and the top-layer conductive line 02 can be connected to the package substrate through the RDL or other structures, thereby establishing an electrical connection between the chip and the package substrate.

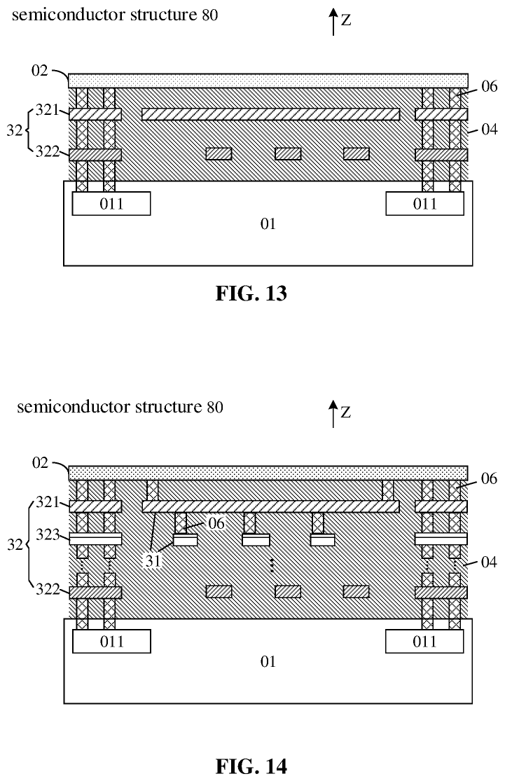

In some embodiments of the present disclosure, as illustrated in FIG. 13, in a case that N is equal to 2 (i.e. the number of layers of the secondary-top-layer conductive lines is equal to 2), the peripheral area wires 32 include the first peripheral area wires 321 and the second peripheral area wires 322. The first peripheral area wires 321 and the second peripheral area wires 322 are continuously arranged in the vertical direction Z, and are alternately arranged in a direction away from the top-layer conductive line 02.

As illustrated in FIG. 13, a first end of the first peripheral area wires 321 is connected to the top-layer conductive line 02, a second end of the first peripheral area wires 321 is connected to a first end of the second peripheral area wires 322, and a second end of the second peripheral area wires 322 is connected to a semiconductor test device 011 formed in the substrate 01.

It can be understood that in a case that the number of layers of the secondary-top-layer conductive lines is 2, an electrical connection is established between the top-layer conductive line 02 and the semiconductor test device 011 through the first peripheral area wires 321 and the second peripheral area wires 322. The top-layer conductive line 02 can be connected to the package substrate through the RDL or other structures, thereby establishing an electrical connection between the chip and the package substrate.

In some embodiments of the present disclosure, as illustrated in FIGS. 12 and 13, the semiconductor structure 80 further includes conductive vias 06. The conductive vias 06 extend in the vertical direction Z. The conductive vias 06 penetrate the multiple dielectric layers 04 and are filled with conductive material, so as to conductively connect adjacent peripheral area wires 32. The conductive vias 06 conductively connect the first peripheral area wires 321 and the top-layer conductive line 02, and conductively connect the second peripheral area wires 322 and the semiconductor test device 011. That is, the connection between the peripheral area wires 32 and the top-layer conductive line 02, the connection between adjacent peripheral area wires 32, and the connection between the peripheral area wires 32 and the semiconductor test device 011 are achieved by the conductive vias 06.

In some embodiments of the present disclosure, as illustrated in FIG. 14, the conductive vias 06 further conductively connect: adjacent central area wires 31, and/or the central area wires 31 and the top-layer conductive line 02. It should be noted that each layer of the central area wires 31 may not be connected to the conductive vias 06, or may be partially connected to the conductive vias 06. Connecting the central area wires 31 to the conductive vias 06 is helpful to discharge electric charges. Each layer of peripheral area wires 32 should be connected to the conductive vias 06 to turn on the semiconductor test device 011.

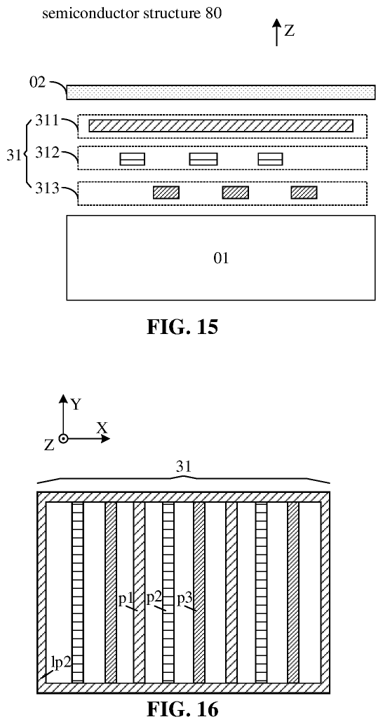

In some embodiments of the present disclosure, FIG. 15 is a diagram of an optional semiconductor structure according to an embodiment of the present disclosure. As illustrated in FIG. 15, in a case that N is equal to 3 (i.e. the number of layers of the secondary-top-layer conductive lines is equal to 3), the central area wires 31 include first central area wires 311, second central area wires 312, and third central area wires 313. The first central area wires 311, the second central area wires 312 and the third central area wires 313 are continuously arranged in the vertical direction, and are sequentially arranged in a direction away from the top-layer conductive line 02. A projection of the first central area wires 311 on the top surface of the substrate 01 includes a first pattern. A projection of the second central area wires 312 on the top surface of the substrate 01 includes multiple second patterns extending in the first direction. A projection of the third central area wires 313 on the top surface of the substrate 01 includes multiple third patterns extending in the first direction.

In some embodiments of the present disclosure, as illustrated in FIG. 16, the first pattern includes first strip patterns p1 and a second annular pattern 1p2, the multiple second patterns are second strip patterns p2, and the multiple third patterns are third strip patterns p3. The first strip patterns p1 extend in the first direction Y. The second annular pattern 1p2 surrounds the first strip patterns p1, the second strip patterns p2 and the third strip patterns p3.

The first strip patterns p1, the second strip patterns p2 and the third strip patterns p3 are alternately arranged in a predetermined order in the second direction X. FIG. 16 illustrates a case of a predetermined order. In the embodiment of the present disclosure, the predetermined order includes at least one of the following: a sequence or reverse sequence of the first strip patterns p1, the second strip patterns p2 and the third strip patterns p3; a sequence or reverse sequence of the second strip patterns p2, the first strip patterns p1 and the third strip patterns p3; or a sequence or reverse sequence of the first strip patterns p1, the third strip patterns p3 and the second strip patterns p2.

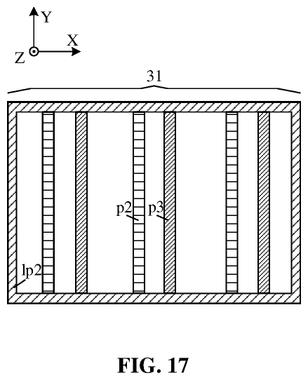

In some embodiments of the present disclosure, as illustrated in FIG. 17, the first pattern is the second annular pattern 1p2, the second patterns are second strip patterns p2, and the third patterns are third strip patterns p3. The second annular pattern 1p2 surrounds the second strip patterns p2 and the third strip patterns p3. The second strip patterns p2 and the third strip patterns p3 are alternately arranged in the second direction X.

It should be noted that in the present disclosure, the terms “include”, “comprise” or any other variations thereof are intended to encompass non-exclusive inclusion, so that a process, method, article or device including a series of elements includes not only those elements, but also other elements not explicitly listed, or also includes elements inherent to such process, method, article or device. Without further restrictions, the element defined by the terms “ includes an . . . ” does not exclude that there are other identical elements in the process, method, article or device including this element.

The above serial numbers of the embodiments of the present disclosure are for description only and do not represent advantages and disadvantages of the embodiments. The methods disclosed in the method embodiments of the present disclosure can be arbitrarily combined without conflict to obtain new method embodiments. Features disclosed in thel product embodiments of the present disclosure can be arbitrarily combined without conflict to obtain new product embodiments. Features disclosed in the method or device embodiments of the present disclosure can be arbitrarily combined without conflict to obtain new method or device embodiments.

The foregoing descriptions are merely specific embodiments of the present disclosure, but the scope of protection of the present disclosure is not limited thereto. Any change or replacement readily contemplated by a person skilled in the art within the technical scope disclosed in the present disclosure shall fall within the scope of protection of the present disclosure. Accordingly, the scope of protection of the present disclosure shall be subject to the scope of protection of the claims.

Embodiments of the present disclosure provide a semiconductor structure configured to form a pad. The semiconductor structure includes a substrate, a top-layer conductive line, N layers of secondary-top-layer conductive lines and multiple dielectric layers. N is an integer greater than or equal to 2. The top-layer conductive line and the N layers of the secondary-top-layer conductive lines are arranged above the substrate. The N layers of the secondary-top-layer conductive lines are arranged on a side of the top-layer conductive line close to the substrate, and each of the multiple dielectric layers is located between two respective adjacent layers of the secondary-top-layer conductive lines in a vertical direction. For the N layers of the secondary-top-layer conductive lines, an area in which projections of any two layers of the secondary-top-layer conductive lines on a top surface of the substrate overlap with each other is less than a first threshold.

On the one hand, since a size of the parasitic capacitance is proportional to an area in which the two conductors generating the parasitic capacitance face each other, the area in which projections of any two layers of the secondary-top-layer conductive lines on the top surface of the substrate overlap with each other is controled to be less than the first threshold (i.e. an area in which the two layers of the secondary-top-layer conductive lines face each other is reduced), thereby reducing the parasitic capacitance of the pad and reduce and reducing interference to the signal.

On the other hand, the N layers of the secondary-top-layer conductive lines are arranged on the side of the top-layer conductive line close to the substrate, and each of the multiple dielectric layers is located between two respective adjacent layers of the secondary-top-layer conductive lines in a vertical direction. That is, the secondary-top-layer conductive lines and the multiple dielectric layers are alternately arranged below the top-layer conductive line, thereby improving density uniformity of material under the top-layer conductive line and meeting the planarization requirements in the subsequent process.

1. A semiconductor structure, configured to form a pad, the semiconductor structure comprising: a substrate, a top-layer conductive line, N layers of secondary-top-layer conductive lines and a plurality of dielectric layers, N being an integer greater than or equal to 2,
wherein the top-layer conductive line and the N layers of the secondary-top-layer conductive lines are arranged above the substrate, the N layers of the secondary-top-layer conductive lines are arranged on a side of the top-layer conductive line close to the substrate, and each of the plurality of dielectric layers is located between two respective adjacent layers of the secondary-top-layer conductive lines in a vertical direction, and
wherein for the N layers of the secondary-top-layer conductive lines, an area in which projections of any two layers of the secondary-top-layer conductive lines on a top surface of the substrate overlap with each other is less than a first threshold.

2. The semiconductor structure of claim 1, wherein the semiconductor structure further comprises a first region configured to form a redistribution layer,
wherein the first region is arranged on a side of the top-layer conductive line away from the substrate, and
wherein a projection of the N layers of the secondary-top-layer conductive lines on the top surface of the substrate at least partially overlaps with a projection of the first region on the top surface of the substrate.

3. The semiconductor structure of claim 2, wherein the N layers of the secondary-top-layer conductive lines comprise a first secondary-top-layer conductive line, the first secondary-top-layer conductive line being closest to the top-layer conductive line among the N layers of the secondary-top-layer conductive lines, and
wherein a projection of the first secondary-top-layer conductive line on the top surface of the substrate covers the projection of the first region on the top surface of the substrate.

4. The semiconductor structure of claim 1, wherein the N layers of secondary-top-layer conductive lines comprise central area wires, and
wherein a projection of the central area wires on the top surface of the substrate comprises a plurality of patterns extending in a first direction, the plurality of patterns are spaced in a second direction, and the second direction is perpendicular to the first direction.

5. The semiconductor structure of claim 4, wherein a spacing in the second direction between two adjacent patterns corresponding to each layer of the secondary-top-layer conductive lines is greater than or equal to a second threshold, and
wherein a respective maximum width of each of the plurality of patterns in the second direction is less than or equal to a third threshold.

6. The semiconductor structure of claim 4, wherein the N layers of the secondary-top-layer conductive lines further comprise peripheral area wires, and
wherein a projection of the peripheral area wires on the top surface of the substrate comprises a first annular pattern, and the first annular pattern surrounds the projection of the central area wires on the top surface of the substrate.

7. The semiconductor structure of claim 6, wherein N is equal to 2,
wherein the peripheral area wires comprise first peripheral area wires and second peripheral area wires, and the first peripheral area wires and the second peripheral area wires are continuously arranged in the vertical direction, and
wherein a first end of the first peripheral area wires is connected to the top-layer conductive line, a second end of the first peripheral area wires is connected to a first end of the second peripheral area wires, and a second end of the second peripheral area wires is connected to a semiconductor test device formed in the substrate.

8. The semiconductor structure of claim 6, wherein N is equal to 2,
wherein the peripheral area wires comprise first peripheral area wires, second peripheral area wires, and at least one layer of third peripheral area wires, and the first peripheral area wires, the at least one layer of the third peripheral area wires and the second peripheral area wires are continuously arranged in the vertical direction, and
wherein a first end of the first peripheral area wires is connected to the top-layer conductive line, a second end of the first peripheral area wires is connected to a first end of the at least one layer of the third peripheral area wires, a first end of the second peripheral area wires is connected to a second end of the at least one layer of the third peripheral area wires, and a second end of the second peripheral area wires is connected to a semiconductor test device formed in the substrate.

9. The semiconductor structure of claim 7, wherein the semiconductor structure further comprises conductive vias,
the conductive vias extend in the vertical direction,
the conductive vias penetrate the plurality of dielectric layers, so as to conductively connect adjacent peripheral area wires, and
the conductive vias conductively connect the first peripheral area wires and the top-layer conductive line and conductively connect the second peripheral area wires and the semiconductor test device.

10. The semiconductor structure of claim 9, wherein the conductive vias further conductively connect at least one the following:
adjacent central area wires; or
the central area wires and the top-layer conductive line.

11. The semiconductor structure of claim 6, wherein a minimum spacing between the projection of the peripheral area wires on the top surface of the substrate and the projection of the central area wires on the top surface of the substrate is greater than or equal to a fourth threshold.

12. The semiconductor structure of claim 1, wherein a material of the plurality of dielectric layers is an insulating material, and a material of the top-layer conductive line and a material of the N layers of the secondary-top-layer conductive lines are metal.

13. The semiconductor structure of claim 4, wherein N is equal to 3,
wherein the central area wires comprise first central area wires, second central area wires, and third central area wires, and the first central area wires, the second central area wires and the third central area wires are continuously arranged in the vertical direction,
wherein a projection of the first central area wires on the top surface of the substrate comprises a first pattern, a projection of the second central area wires on the top surface of the substrate comprises a plurality of second patterns extending in the first direction, and a projection of the third central area wires on the top surface of the substrate comprises a plurality of third patterns extending in the first direction.

14. The semiconductor structure of claim 13, wherein the first pattern comprises first strip patterns and a second annular pattern, the plurality of second patterns are second strip patterns, and the plurality of third patterns are third strip patterns,
wherein the first strip patterns extend in the first direction, the second annular pattern surrounds the first strip patterns, the second strip patterns, and the third strip patterns, and the first strip patterns, the second strip patterns and the third strip patterns are alternately arranged in a predetermined order in the second direction.

15. The semiconductor structure of claim 13, wherein the first pattern is a second annular pattern, the plurality of second patterns are second strip patterns, and the plurality of third patterns are third strip patterns,
wherein the second annular pattern surrounds the second strip patterns and the third strip patterns, and the second strip patterns and the third strip patterns are alternately arranged in the second direction.

16. The semiconductor structure of claim 14, wherein the predetermined order comprises at least one of:
a sequence or reverse sequence of the first strip patterns, the second strip patterns and the third strip patterns;
a sequence or reverse sequence of the second strip patterns, the first strip patterns and the third strip patterns; or
a sequence or reverse sequence of the first strip patterns, the third strip patterns and the second strip patterns.
